(19) United States
(12) Patent Application Publication
(10) Pub. No.: US 2022/0310582 A1
(43) Pub. Date: Sep. 29, 2022

(54) SEMICONDUCTOR DEVICE

(71) Applicant: KABUSHIKI KAISHA TOSHIBA, Tokyo (JP)

(72) Inventors: Susumu OBATA, Yokohama (JP); Kazuhito HIGUCHI, Yokohama (JP); Mitsuo SANO, Kamakura (JP); Takayuki TAJIMA, Sagamihara (JP)

(73) Assignee: KABUSHIKI KAISHA TOSHIBA, Tokyo (JP)

(21) Appl. No.: 17/473,350

(22) Filed: Sep. 13, 2021

(30) Foreign Application Priority Data
Mar. 23, 2021 (JP) 2021-048957

(51) Int. Cl. H01L 27/01; H03H 7/01; H01L 49/02; H01L 21/70

(52) U.S. Cl. CPC H01L 27/013; H03H 7/0115; H01L 28/10; H01L 28/91; H01L 21/705

(57) ABSTRACT

According to an embodiment, a semiconductor device includes a layer stack including a conductive substrate containing semiconductor material and including a first main surface provided with one or more recesses and a second main surface opposite to the first main surface, a conductive layer covering at least part of the first main surface and side walls and bottom surfaces of the one or more recesses, and a dielectric layer interposed between the conductive substrate and the conductive layer, the conductive layer and a portion of the conductive substrate adjacent to the dielectric layer being an upper electrode and a lower electrode of a capacitor, respectively, an insulating layer provided on the capacitor or on the second main surface, and an inductor provided on the insulating layer at a position of the capacitor.

### CROSS-REFERENCE TO RELATED APPLICATIONS

This application is based upon and claims the benefit of priority from Japanese Patent Applications No. 2021-048957, filed Mar. 23, 2021, the entire contents of which are incorporated herein by reference.

### FIELD

Embodiments described herein relate generally to a semiconductor device.

### BACKGROUND

A combination of a capacitor and an inductor is sometimes used in an LC filter. An LC filter allows components in a specific frequency band of an electrical signal from or to an integrated circuit (IC) to pass therethrough while blocking components in the other frequency band as noise.

### BRIEF DESCRIPTION OF THE DRAWINGS

FIG. 1 is a top view of a semiconductor device according to one embodiment;

FIG. 2 is a cross-sectional view of the semiconductor device shown in FIG. 1, taken along line II-II;

FIG. 3 is a cross-sectional view showing an example of a semiconductor package including the semiconductor device shown in FIGS. 1 and 2;

FIG. 4 is an equivalent circuit schematic of the semiconductor package shown in FIG. 3;

FIG. 5 is a cross-sectional view showing a process in the manufacture of the semiconductor device shown in FIGS. 1 and 2;

FIG. 6 is a cross-sectional view showing another process in the manufacture of the semiconductor device shown in FIGS. 1 and 2;

FIG. 7 is a cross-sectional view showing yet another process in the manufacture of the semiconductor device shown in FIGS. 1 and 2;

FIG. 8 is a plan view showing an inductor according to a modification; and

FIG. 9 is an equivalent circuit schematic of a semiconductor package according to a modification.

### DETAILED DESCRIPTION

Embodiments will be described in detail below with reference to the accompanying drawings. Constituent elements that perform the same function or similar functions are assigned the same reference numerals throughout the drawings, and redundant descriptions will be omitted.

<Semiconductor Device>

A semiconductor device according to one embodiment comprises a layer stack including a conductive substrate containing semiconductor material and including a first main surface provided with one or more recesses and a second main surface opposite to the first main surface, a conductive layer covering at least part of the first main surface and side walls and bottom surfaces of the one or more recesses, and a dielectric layer interposed between the conductive substrate and the conductive layer, the conductive layer and a portion of the conductive substrate adjacent to the dielectric layer being an upper electrode and a lower electrode of a capacitor, respectively, an insulating layer provided on the capacitor or on the second main surface, and an inductor provided on the insulating layer at a position of the capacitor.

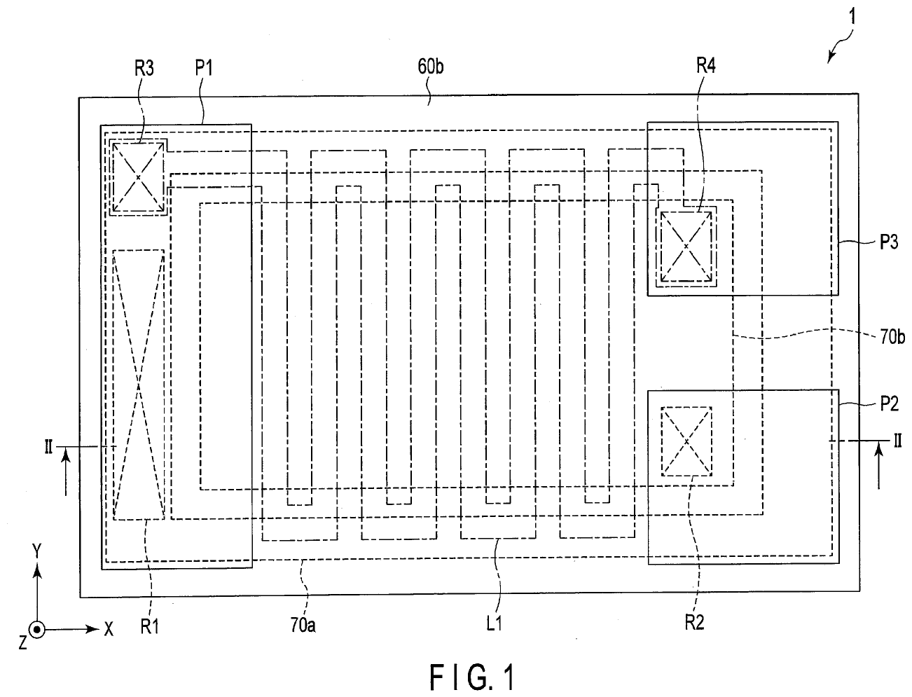

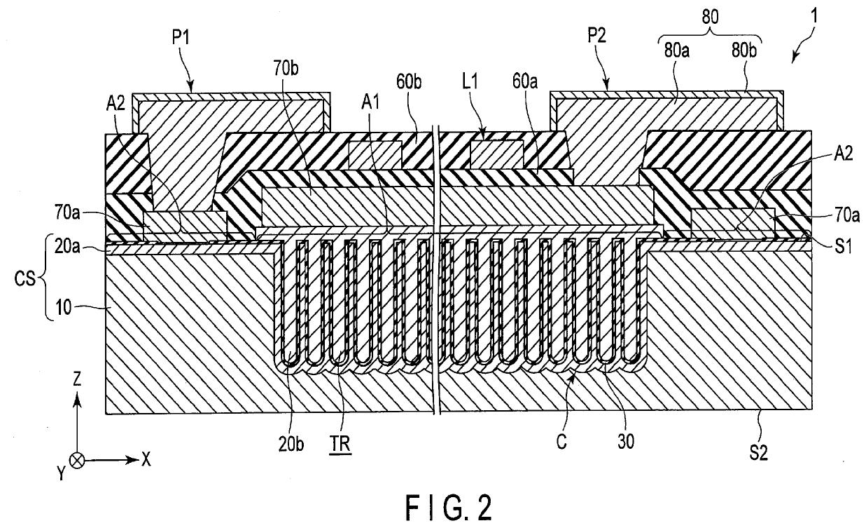

FIGS. 1 and 2 show a semiconductor device according to an embodiment.

A semiconductor device 1 shown in FIGS. 1 and 2 includes a conductive substrate CS, a conductive layer 20b, and a dielectric layer 30, as shown in FIG. 2. The conductive layer 20b and a portion of the conductive substrate CS adjacent to the dielectric layer 30 are an upper electrode and a lower electrode of a capacitor C, respectively.

In each figure, the X direction is a direction parallel to a main surface of the conductive substrate CS, and the Y direction is a direction perpendicular to the X direction and parallel to the main surface of the conductive substrate CS. The Z direction is a thickness direction of the conductive substrate CS, i.e., a direction perpendicular to the X direction and the Y direction.

The conductive substrate CS contains a semiconductor material such silicon. The conductive substrate CS is a substrate having electrical conductivity at least in its surface facing the conductive layer 20b. As mentioned above, a part of the conductive substrate CS serves as the lower electrode of the capacitor C.

The conductive substrate CS has a first main surface S1, a second main surface S2, which is opposite to the first main surface S1, and an end surface extending from an edge of the first main surface S1 to an edge of the second main surface S2. Here, the conductive substrate CS has a flat and approximately right-angled parallelepiped shape. The conductive substrate CS may have other shapes.

The first main surface S1, which is the top surface of the conductive substrate CS here, includes a first region A1 and a second region A2. The first region A1 and the second region A2 are adjacent to each other. Here, the first region A1 is rectangular, and the second region A2 surrounds the first region A1.

In the first region A1, a plurality of recesses TR each having a shape extending in one direction and arranged in the width direction are provided. The recesses TR are spaced apart from one another. Here, these recesses TR are a plurality of trenches arranged in the width direction, specifically, a plurality of trenches extending in the Y direction and arranged in the X direction.

Portions of the conductive substrate CS each sandwiched between one and the other of adjacent recesses TR are projections. The projections each have a shape extending in the Y direction, and are arranged in the X direction. That is, in the first region A1, a plurality of wall parts each having a shape extending in the Y direction and the Z direction and arranged in the X direction are provided as the projections.

The “length direction” of the recesses or the projections is a length direction of orthogonal projections of the recesses or the projections onto a plane perpendicular to the thickness direction of the conductive substrate.

A length of an opening of each recess TR is within a range of 5 μm to 500 μm according to an example, and within a range of 50 μm to 100 μm according to another example.

A width of the opening of the recess TR, i.e., a distance between the projections adjacent in the width direction, is preferably 0.3 μm or more. When this width or distance is reduced, a larger electric capacitance can be achieved. However, if this width or distance is reduced, it becomes difficult to form a stack structure including the dielectric layer 30 and the conductive layer 20b in the recesses TR.

A depth of the recesses TR or a height of the projections is within a range of 5 μm to 300 μm according to an example, and within a range of 50 μm to 100 μm according to another example.

A distance between the recesses TR adjacent in the width direction, i.e., a thickness of each projection, is preferably 0.1 μm or more. When this distance or thickness is reduced, a larger electric capacitance can be achieved. However, if this distance or thickness is reduced, the projections are likely to be damaged.

Here, cross sections of the recesses TR perpendicular to the length direction are rectangular. However, these cross sections need not be rectangular. For example, these cross sections may have a tapered shape. Here, a plurality of trenches are provided as the recesses TR; however, one or more recesses may be provided in such a manner that a plurality of pillar-like projections are provided.

The conductive substrate CS includes a substrate 10 and a conductive layer 20a.

The substrate 10 has a shape similar to that of the conductive substrate CS. The substrate 10 is a substrate containing a semiconductor material, such as a semiconductor substrate. The substrate 10 is preferably a substrate containing silicon, such as a silicon substrate. Such a substrate can be processed using semiconductor processes.

The conductive layer 20a is provided on the substrate 10. The conductive layer 20a serves as a lower electrode of the capacitor C.

The conductive layer 20a is made of, for example, silicon or polysilicon doped with impurities to improve the electrical conductivity, or a metal such as molybdenum, aluminum, gold, tungsten, platinum, nickel, or copper, or an alloy thereof. The conductive layer 20a may have a single-layer structure or a multi-layer structure.

The thickness of the conductive layer 20a is preferably in a range of 0.05 μm to 10 μm, and more preferably in a range of 0.1 μm to 5 μm. If the conductive layer 20a is thin, a discontinuous portion may be caused in the conductive layer 20a, or a sheet resistance of the conductive layer 20a may become excessively large. If the conductive layer 20a is thickened, manufacturing costs increase.

Here, as an example, let us assume that the substrate 10 is a semiconductor substrate such as a silicon substrate, and the conductive layer 20a is a high-concentration doped layer obtained by doping a surface region of the semiconductor substrate with impurities at a high concentration. In this case, the projections, if thin enough, can be entirely doped with impurities at a high concentration.

The conductive layer 20b serves as the upper electrode of the capacitor. The conductive layer 20b is provided on the first region A1, and covers the sidewalls and bottom surfaces of the recesses TR.

The conductive layer 20b is made of, for example, polysilicon doped with impurities to improve the electrical conductivity, or a metal such as molybdenum, aluminum, gold, tungsten, platinum, nickel, or copper, or an alloy thereof. The conductive layer 20b may have a single-layer structure or a multi-layer structure.

The thickness of the conductive layer 20b is preferably within a range of 0.05 μm to 3 μm, and more preferably within a range of 0.1 μm to 1.5 μm. If the conductive layer 20b is thin, a discontinuous portion may be caused in the conductive layer 20b, or a sheet resistance of the conductive layer 20b may become excessively large. If the conductive layer 20b is thick, it may be difficult to form the conductive layer 20a and the dielectric layer 30 with sufficient thicknesses.

In FIG. 2, the conductive layer 20b is provided so that the recesses TR are completely filled with the conductive layer 20b and the dielectric layer 30. The conductive layer 20b may be a layer that is conformal to the surface of the conductive substrate CS. That is, the conductive layer 20b may be a layer having an approximately uniform thickness. In this case, the recesses TR are not completely filled with the conductive layer 20b and the dielectric layer 30.

The dielectric layer 30 is interposed between the conductive substrate CS and the conductive layer 20b. The dielectric layer 30 is a layer that is conformal to the surface of the conductive substrate CS. The dielectric layer 30 electrically insulates the conductive substrate CS and the conductive layer 20b from each other. The capacitor C is a stack of the conductive layer 20a, the dielectric layer 30, and the conductive layer 20b.

The dielectric layer 30 is made of, for example, an organic dielectric or an inorganic dielectric. As the organic dielectric, for example, polyimide can be used. As the inorganic dielectric, a ferroelectric can be used; however, paraelectrics such as silicon nitride, silicon oxide, silicon oxynitride, titanium oxide, and tantalum oxide, are preferable. These paraelectrics have a small change in dielectric constant with temperature. Therefore, when the paraelectrics are used for the dielectric layer 30, the heat resistance of the semiconductor device 1 can be improved.

The thickness of the dielectric layer 30 is preferably within a range of 0.005 μm to 0.5 μm, and more preferably within a range of 0.01 μm to 0.1 μm. If the dielectric layer 30 is thin, a discontinuous portion may be caused in the dielectric layer 30, and the conductive substrate CS and the conductive layer 20b may be short-circuited. Further, if the dielectric layer 30 is thinned, the withstand voltage falls even without a short circuit, and the possibility that a short circuit will occur when a voltage is applied increases. If the dielectric layer 30 is thickened, the withstand voltage increases, but the electric capacitance decreases.

The dielectric layer 30 is opened at a position of the second region A2. That is, the dielectric layer 30 allows the conductive layer 20a to be exposed at this position. Here, a portion of the dielectric layer 30 provided on the first main surface S1 is opened in a frame shape.

The semiconductor device 1 further includes an insulating layer 60a, a first internal electrode 70a, a second internal electrode 70b, an inductor L1, an insulating layer 60b, a first external connection terminal P1, a second external connection terminal P2, and a third external connection terminal P3, as shown in FIGS. 1 and 2.

The second internal electrode 70b is provided on the first region A1. The second internal electrode 70b is electrically connected to the conductive layer 20b. Here, the second internal electrode 70b is a rectangular electrode located at a center of the first main surface S1.

The first internal electrode 70a is provided on the second region A2. The first internal electrode 70a is in contact with the conductive substrate CS at a position of the opening provided in the dielectric layer 30. The first internal electrode 70a is thereby electrically connected to the conductive substrate CS. Here, the first internal electrode 70a is a frame-shaped electrode arranged to surround the second internal electrode 70b.

The first internal electrode 70a and the second internal electrode 70b may have a single-layer structure or a multi-layer structure. Each layer constituting the first internal electrode 70a and the second internal electrode 70b is made of, for example, a metal such as molybdenum, aluminum, gold, tungsten, platinum, copper, or nickel, or an alloy containing one or more of the metals.

The insulating layer 60a covers portions of the conductive layer 20b and the dielectric layer 30 which are located on the first main surface S1, as well as the first internal electrode 70a and the second internal electrode 70b. The insulating layer 60a is opened at positions corresponding to a part of the first internal electrode 70a and a part of the second internal electrode 70b.

The insulating layer 60a may have a single-layer structure or a multi-layer structure. Each layer constituting the insulating layer 60a is made of, for example, an inorganic insulator such as silicon nitride or silicon oxide, or an organic insulator such as polyimide or novolac resin. The insulating layer 60a is preferably made of an inorganic insulator.

The thickness of the insulating layer 60a is preferably within a range of 0.1 μm to 20 μm, and more preferably within a range of 1 μm to 3 μm, at the position of the capacitor C. If the insulating layer 60a is thinned, a short circuit between the second internal electrode 70b and the inductor L1 is likely to occur, or the parasitic capacitance therebetween will increase. A thick insulating layer 60a is expensive.

The inductor L1 is provided on the insulating layer 60a at the position of the capacitor C. Here, the inductor L1 is a meander inductor. Namely, the inductor L1 is a conductor layer patterned to form a meandering conductor path. The meander inductor is also called meander wiring.

The inductor L1 may have a single-layer structure or a multi-layer structure. For example, when being formed by plating, the inductor L1 may include an adhesion layer, a seed layer, and a plating layer.

The inductor L1 or one or more layers included therein is made of a metal such as aluminum, copper, or nickel, or an alloy including one or more of the metals. When the inductor L1 is formed by plating, the adhesion layer may contain a metal such as titanium or molybdenum. An adhesion layer containing titanium may serve as a barrier layer. The seed layer may contain a metal such as copper. The plating layer may contain a metal such as copper or nickel.

The thickness of the conductor layer constituting the inductor L1 is preferably within a range of 0.1 μm to 10 μm, and more preferably within a range of 1 μm to 3 μm. If this conductor layer is thickened, the resistance value of the inductor L1 is decreased. However, a thick conductor layer is expensive.

The width of the conductor path constituting the inductor L1 is preferably within a range of 1 μm to 100 μm, and more preferably within a range of 5 μm to 50 μm. If the width is increased, the resistance value of the inductor L1 is decreased. However, if the width is increased, it becomes difficult to form a long conductor path.

The length of the conductor path constituting the inductor L1 is preferably within a range of 1 mm to 1000 mm, and more preferably within a range of 20 mm to 200 mm. If the conductor path is lengthened, the inductance of the inductor L1 is increased. However, if the conductor path is lengthened, a need to decrease the width or spacing of the conductor path may arise.

The insulating layer 60b covers the insulating layer 60a and the inductor L1. The insulating layer 60b is opened at the positions of the two openings provided in the insulating layer 60a, the position of one end of the inductor L1, and the position of the other end of the inductor L1.

The insulating layer 60b may have a single-layer structure or a multi-layer structure. For each layer constituting the insulating layer 60b, for example the materials described as examples for the insulating layer 60a can be used.

The first external connection terminal P1, the second external connection terminal P2, and the third external connection terminal P3 are electrode pads that enable connection from the circuits included in the semiconductor device 1 to external circuits.

The first external connection terminal P1 is provided on the insulating layer 60b. The first external connection terminal P1 is in contact with the first internal electrode 70a at the position of one opening provided in the insulating layer 60b. The first external connection terminal P1 is also in contact with one end of the inductor L1 at the position of another opening provided in the insulating layer 60b. The first external connection terminal P1 is thereby electrically connected to the first internal electrode 70a and one end of the inductor L1. In FIG. 1, a region R1 is a region where the first external connection terminal P1 is in contact with the first internal electrode 70a. A region R3 is a region where the first external connection terminal P1 is in contact with one end of the inductor L1.

The second external connection terminal P2 is provided on the insulating layer 60b. The second external connection terminal P2 is in contact with the second internal electrode 70b at the position of yet another opening provided in the insulating layer 60b. The second external connection terminal P2 is thereby electrically connected to the second internal electrode 70b. In FIG. 1, a region R2 is a region where the second external connection terminal P2 is in contact with the second internal electrode 70b.

The third external connection terminal P3 is provided on the insulating layer 60b. The third external connection terminal P3 is in contact with the other end of the inductor L1 at the position of the remaining one opening provided in the insulating layer 60b. The third external connection terminal P3 is thereby electrically connected to the other end of the inductor L1. In FIG. 1, a region R4 is a region where the third external connection terminal P3 is in contact with the other end of the inductor L1.

Each of the first external connection terminal P1, the second external connection terminal P2, and the third external connection terminal P3 is a part of a conductive layer 80. The conductive layer 80 herein has a stack structure including a first metal layer 80a and a second metal layer 80b.

The first metal layer 80a is made of, for example, copper or nickel. The second metal layer 80b covers the upper and end surfaces of the first metal layer 80a. The second metal layer 80b is constituted by, for example, a layer stack of a nickel or nickel alloy layer and a gold layer. The second metal layer 80b can be omitted.

The conductive layer 80 may further include a barrier layer containing a metal such as titanium on its surface in contact with the insulating layer 60a, the insulating layer 60b, or the like. When the conductive layer 80 is formed by plating, an adhesion layer can be used as a barrier layer. In this case, the conductive layer 80 may further include a seed layer including a metal, such as copper, between the adhesion layer and the first metal layer 80a.

The semiconductor device 1 may further include a bonding conductor on each of the first external connection terminal P1, the second external connection terminal P2, and the third external connection terminal P3. As the bonding conductor, a metal bump, such as a gold bump or a solder bump, can be provided.

<Semiconductor Package>

A semiconductor package according to one embodiment comprises a semiconductor chip including an integrated circuit, and the semiconductor device according to the above described embodiment, the first external connection terminal being connected to the integrated circuit.

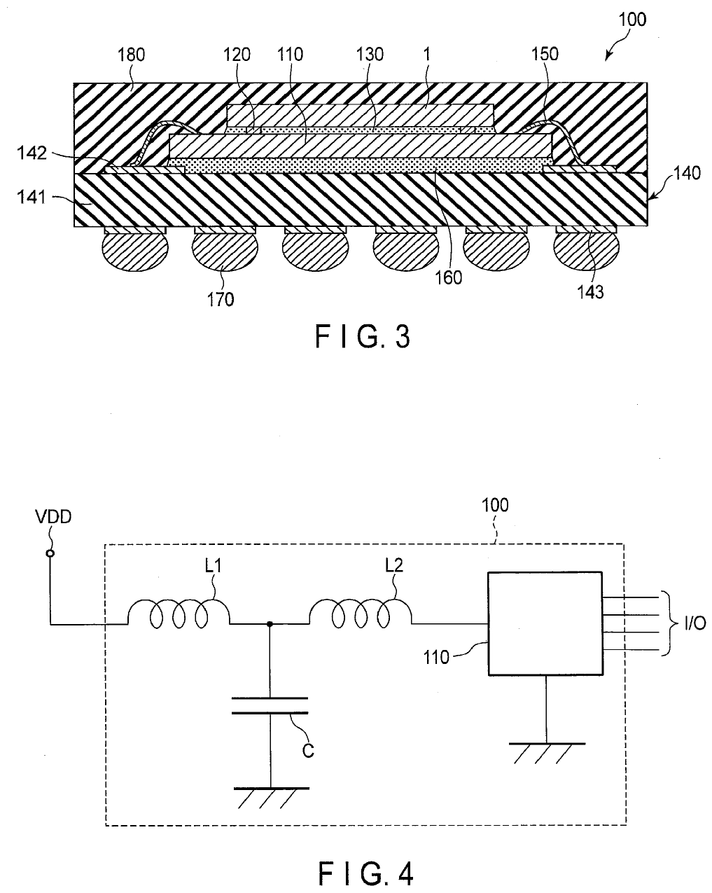

FIG. 3 shows a semiconductor package according to an embodiment.

A semiconductor package 100 shown in FIG. 3 includes the above-described semiconductor device 1, a semiconductor chip 110, and a wiring board 140.

The wiring board 140 is an interposer that mediates mounting of the semiconductor chip 110 on a mother board or the like. Here, the wiring board 140 is that for a ball grid array (BGA).

The wiring board 140 includes a multi-layer interconnection structure 141 and electrode pads 142 and 143. The multi-layer interconnection structure 141 includes an insulating layer, a conductor pattern, and a through-via electrode for interlayer connection. The electrode pads 142 are provided on one main surface of the multi-layer interconnection structure 141, and are electrically connected to the conductor pattern of the multi-layer interconnection structure 141. The electrode pads 143 are provided on the other main surface of the multi-layer interconnection structure 141, and are electrically connected to the conductor pattern of the multi-layer interconnection structure 141.

The semiconductor chip 110 includes an integrated circuit such as a large-scale integrated circuit. At least part of the integrated circuit may constitute a microprocessor such as a central processing unit, or a microcontroller.

The semiconductor chip 110 further includes an external connection terminal for power supply, an external connection terminal for grounding, external connection terminals for signal input, and external connection terminals for signal output. These external connection terminals are electrically connected to the integrated circuit. The semiconductor chip 110 further includes, on its surface, a conductor pattern electrically insulated from the integrated circuit.

The semiconductor chip 110 is mounted on the wiring board 140. Specifically, the semiconductor chip 110 is fixed to the wiring board 140 by an adhesive layer 160 made from a die bonding agent. The external connection terminals of the semiconductor chip 110 are connected to the electrode pads 142 via bonding conductors 150, which are metal wires.

The semiconductor device 1 is mounted on the semiconductor chip 110. Specifically, the semiconductor device 1 is fixed to the semiconductor chip 110 by an adhesive layer 130 made from an underfill agent. The first external connection terminal P1, second external connection terminal P2, and third external connection terminal P3 of the semiconductor device 1 are connected, via bonding conductors 120, to the external connection terminal for power supply, external connection terminal for grounding, and conductor pattern, which is electrically insulated from the integrated circuit, of the semiconductor chip 110, respectively.

The semiconductor package 100 further includes bonding conductors 170 and a sealing resin layer 180. The bonding conductors 170 are provided on the electrode pads 143. The bonding conductor 170 are, for example, solder balls. The sealing resin layer 180 is an insulating layer sealing therein the semiconductor device 1, the semiconductor chip 110, the bonding conductors 150, and the like.

FIG. 4 is an equivalent circuit schematic of the semiconductor package 100 shown in FIG. 3.

One end of the inductor L1 of the semiconductor device 1 is connected to a power supply VDD mounted on the mother board, via the third external connection terminal P3 of the semiconductor device 1, the conductor pattern of the semiconductor chip 110, the bonding conductor 150, the wiring board 140, and the like. As described above, the other end of the inductor L1 is connected to the first external connection terminal P1 and the conductive layer 20a, which is the lower electrode of the capacitor C. The conductive layer 20b, which is the upper electrode of the capacitor C, is connected to a grounding terminal of the mother board via the second internal electrode 70b of the semiconductor device 1, the second external connection terminal P2 of the semiconductor device 1, the external connection terminal for grounding of the semiconductor chip 110, the bonding conductor 150, the wiring board 140, and the like.

The first external connection terminal P1 is connected to the integrated circuit of the semiconductor chip 110 via the external connection terminal for power supply of the semiconductor chip 110, and the like. A conductor path L2 connecting the first external connection terminal P1 to the integrated circuit of the semiconductor chip 110 has an inductance although it is much smaller than that of the inductor L1. Thus, the symbol for an inductor is used for the conductor path L2 in FIG. 4.

The signal input/output external connection terminals I/O of the semiconductor chip 110 are connected to signal input/output terminals of the mother board via the bonding conductors 150, the wiring board 140, and the like.

<Manufacturing Method>

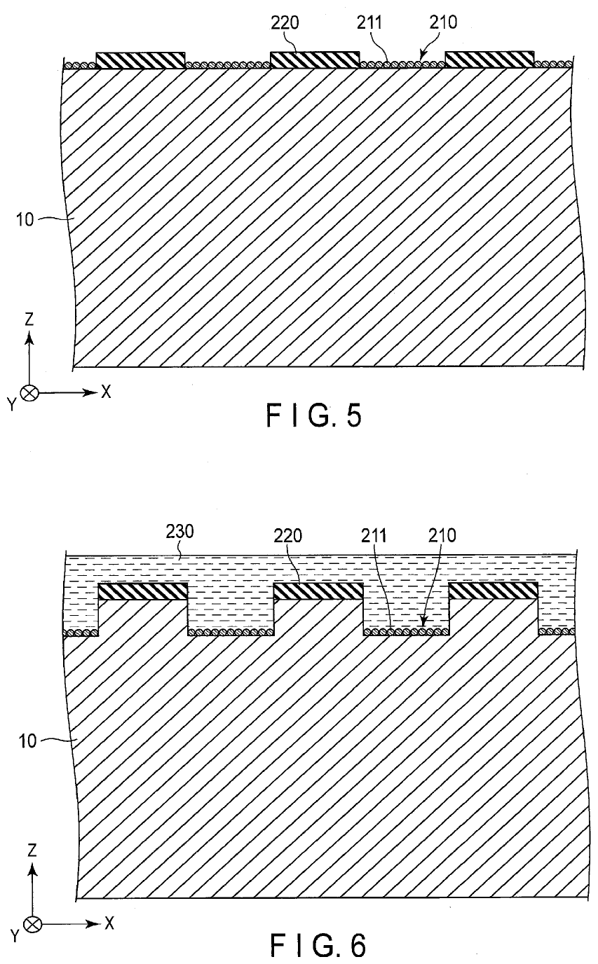

The semiconductor device 1 described with reference to FIGS. 1 and 2 is manufactured by, for example, the following method. Hereinafter, an example of the method of manufacturing the semiconductor device 1 will be described with reference to FIGS. 5 to 7.

In this method, the substrate 10 shown in FIG. 5 is first prepared. Here, as an example, let us assume that the substrate 10 is a single-crystal silicon wafer. The plane orientation of the single-crystal silicon wafer is not particularly limited, but a silicon wafer whose main surface is a (100) plane is used in this example. As the substrate 10, a silicon wafer whose main surface is a (110) plane can also be used.

Next, recesses are formed on the substrate 10 by metal-assisted chemical etching (MacEtch).

That is, as shown in FIG. 5, a catalyst layer 210 containing a noble metal is first formed on the substrate 10. The catalyst layer 210 is formed to partially cover one main surface (hereinafter referred to as a “first surface”) of the substrate 10.

Specifically, a mask layer 220 is first formed on the first surface of the substrate 10.

The mask layer 220 is opened at positions corresponding to the recesses TR. The mask layer 220 prevents portions of the first surface covered with the mask layer 220 from coming into contact with a noble metal to be described later.

Examples of the material of the mask layer 220 include organic materials such as polyimide, fluororesin, phenol resin, acrylic resin, and novolac resin, and inorganic materials such as silicon oxide and silicon nitride.

The mask layer 220 can be formed by, for example, existing semiconductor processes. The mask layer 220 made of an organic material can be formed by, for example, photolithography. The mask layer 220 made of an inorganic material can be formed by, for example, formation of an inorganic material layer by a vapor deposition method, formation of a mask by photolithography, and patterning of the inorganic material layer by etching. Alternatively, the mask layer 220 made of an inorganic material can be formed by oxidation or nitriding of the surface region of the substrate 10, formation of a mask by photolithography, and patterning of an oxide or nitride layer by etching. The mask layer 220 can be omitted.

Next, the catalyst layer 210 is formed on the regions of the first surface which are not covered with the mask layer 220. The catalyst layer 210 is, for example, a discontinuous layer containing a noble metal. Here, as an example, let us assume that the catalyst layer 210 is a particulate layer formed of catalyst particles 211 containing a noble metal.

The noble metal is, for example, one or more of gold, silver, platinum, rhodium, palladium, and ruthenium. The catalyst layer 210 and the catalyst particles 211 may further contain a metal other than a noble metal, such as titanium.

The catalyst layer 210 can be formed by, for example, electroplating, reduction plating, or displacement plating. The catalyst layer 210 may be formed by application of a dispersion containing noble metal particles, or a vapor deposition method such as evaporation or sputtering. Of these methods, displacement plating is particularly favorable because it is possible to directly and evenly deposit a noble metal on the regions of the first surface which are not covered with the mask layer 220.

Next, the substrate 10 is etched with an assist from a noble metal as a catalyst to form recesses on the first surface.

Specifically, as shown in FIG. 6, the substrate 10 is etched with an etching agent 230. For example, the substrate 10 is immersed in the etching agent 230 in liquid form to bring the etching agent 230 into contact with the substrate 10.

The etching agent 230 contains an oxidizer and hydrogen fluoride.

The concentration of hydrogen fluoride in the etching agent 230 is preferably within a range of 1 mol/L to 20 mol/L, more preferably within a range of 5 mol/L to 10 mol/L, and further preferably within a range of 3 mol/L to 7 mol/L. When the hydrogen fluoride concentration is low, it is difficult to achieve a high etching rate. When the hydrogen fluoride concentration is high, excess side etching may occur. The oxidizer can be selected from, for example, hydrogen peroxide, nitric acid, AgNO₃, KAuCl₄, HAuCl₄, K₂PtCl₆, H₂PtC₁₆, Fe(NOA₃, Ni(NOA₂, Mg(NOA₂, Na₂S₂O₈, K₂S₂O₈, KMnO₄, and K₂Cr₂O₇. Hydrogen peroxide is favorable as the oxidizer, because no harmful byproducts are produced and a semiconductor element is not contaminated.

The concentration of the oxidizer in the etching agent 230 is preferably within a range of 0.2 mol/L to 8 mol/L, more preferably within a range of 2 mol/L to 4 mol/L, and further preferably within a range of 3 mol/L to 4 mol/L.

The etching agent 230 may further contain a buffer. The buffer contains, for example, at least one of ammonium fluoride and ammonia. In an example, the buffer is ammonium fluoride. In another example, the buffer is a mixture of ammonium fluoride and ammonia.

The etching agent 230 may further contain other components such as water.

When such an etching agent 230 is used, the material of the substrate 10, which is silicon herein, is oxidized only in regions of the substrate 10 which are close to the catalyst particles 211. Oxide generated thereby is dissolved and removed by hydrofluoric acid. Therefore, only the portions close to the catalyst particles 211 are selectively etched.

The catalyst particles 211 move toward the other main surface (hereinafter referred to as a “second surface”) of the substrate 10 as etching progresses, where etching similar to the above is performed. As a result, as shown in FIG. 5, at the position of the catalyst layer 210, etching proceeds from the first surface toward the second surface in a direction perpendicular to the first surface.

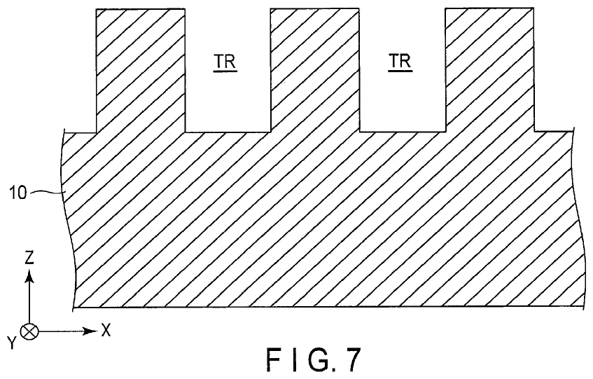

In this way, the recesses TR shown in FIG. 7 are formed on the first surface.

Thereafter, the mask layer 220 and the catalyst layer 210 are removed from the substrate 10.

Next, the conductive layer 20a shown in FIG. 2 is formed on the substrate 10 to obtain the conductive substrate CS. The conductive layer 20a can be formed by, for example, doping the surface region of the substrate 10 with impurities at a high concentration. A conductive layer 20a made of polysilicon can be formed by, for example, low pressure chemical vapor deposition (LPCVD). A conductive layer 20a made of a metal can be formed by, for example, electrolytic plating, reduction plating, or displacement plating.

A plating solution is a liquid containing a salt of a metal to be plated. As the plating solution, a general plating solution such as a copper sulfate plating solution containing copper sulfate pentahydrate and sulfuric acid, a copper pyrophosphate plating solution containing copper pyrophosphate and potassium pyrophosphate, and a nickel sulfamate plating solution containing nickel sulfamate and boron, can be used.

The conductive layer 20a is preferably formed by a plating method using a plating solution containing a salt of a metal to be plated, a surfactant, and carbon dioxide in a supercritical or subcritical state. In this plating method, the surfactant is interposed between particles made of supercritical carbon dioxide and a continuous phase of a solution containing a salt of a metal to be plated. That is, the surfactant is allowed to form micelles in the plating solution, and supercritical carbon dioxide is incorporated in these micelles.

In a normal plating method, supply of the metal to be plated may be insufficient in the vicinity of the bottom portions of the recesses. This is particularly noticeable when a ratio D/W of the depth D to a width or diameter W of the recesses is large.

The micelles incorporating supercritical carbon dioxide can easily enter narrow gaps. As the micelles move, so does the solution containing a salt of a metal to be plated. Therefore, according to the plating method using a plating solution containing a salt of a metal to be plated, a surfactant, and carbon dioxide in a supercritical or subcritical state, the conductive layer 20a having a uniform thickness can be easily formed.

Next, the dielectric layer 30 is formed on the conductive layer 20a. The dielectric layer 30 can be formed by, for example, chemical vapor deposition (CVD). Alternatively, the dielectric layer 30 can be formed by oxidizing, nitriding, or oxynitriding the surface of the conductive layer 20a.

Next, the conductive layer 20b is formed on the dielectric layer 30. As the conductive layer 20b, for example, a conductive layer made of polysilicon or a metal is formed. Such a conductive layer 20b can be formed by, for example, a method similar to the one described above for the conductive layer 20a.

Next, an opening is formed in the dielectric layer 30. Here, a portion of the dielectric layer 30 which is located on the first main surface S1 is opened in a frame shape. This opening can be formed by, for example, formation of a mask by photolithography and patterning by etching.

Next, a metal layer is formed and patterned to obtain the first internal electrode 70a and the second internal electrode 70b. The first internal electrode 70a and the second internal electrode 70b can be formed by, for example, a combination of film formation by sputtering or plating, and photolithography.

Thereafter, the insulating layer 60a is formed. The insulating layer 60a is formed by, for example, CVD.

Next, the inductor L1 is formed on the insulating layer 60a. The inductor L1 can be formed by, for example, a combination of film formation by sputtering or plating, and photolithography.

Next, the insulating layer 60b is formed on the insulating layer 60a and inductor L1. The insulating layer 60b is formed by, for example, CVD. Openings are formed in the insulating layer 60b at the positions of the regions R1, R2, R3, and R4 by photolithography. At this time, openings are also formed in the insulating layer 60a at the positions of the regions R1 and R2.

Next, the first external connection electrode P1, the second external connection terminal P2, and the third external connection terminal P3 are formed on the insulating layer 60b. Specifically, the first metal layer 80a is first formed, and the second metal layer 80b is then formed. The first metal layer 80a and the second metal layer 80h can be formed by, for example, a combination of film formation by sputtering or plating, and photolithography.

Thereafter, the structure thereby obtained is diced. In this way, the semiconductor device 1 shown in FIGS. 1 and 2 is obtained.

### Advantageous Effects

In the above-described semiconductor device 1, the recesses TR are provided on the first main surface S1, and the stack structure including the dielectric layer 30 and the conductive layer 20b is provided not only on the first main surface S1 but also in the recesses TR. Thus, the capacitor C can achieve a large electric capacitance even when the dimension of the semiconductor device 1 in the direction perpendicular to the thickness direction is small.

In the semiconductor device 1, the inductor L1 faces the capacitor C with the insulating layer 60a interposed therebetween. Namely, the inductor L1 and the capacitor C are stacked in the thickness direction of the semiconductor device 1 with the insulating layer 60a interposed therebetween. This arrangement can minimize an increase in the dimension of the semiconductor device 1 in the direction perpendicular to the thickness direction caused by provision of the inductor L1.

Therefore, the semiconductor device 1 can be downsized. In addition, the inductor L1 is a patterned conductor layer. Thus, an increase in the thickness of the semiconductor device 1 caused by provision of the inductor L1 is small. Since the conductive substrate CS and the like are thin, the semiconductor device 1 can have a low height.

As described above, the semiconductor device 1 can be downsized. In the semiconductor package 100, such a semiconductor device 1 and the semiconductor chip 110 are stacked in the thickness direction. Thus, the semiconductor package 100, which includes the semiconductor device 1, can also be downsized, and a semiconductor module obtained by mounting the semiconductor package 100 and the like on the mother board can also be downsized.

In addition, the semiconductor device 1 can have a low height, as described above. Thus, although including the semiconductor device 1 and semiconductor chip 110 stacked in the thickness direction, the semiconductor package 100 can have a low height.

In the semiconductor device 1, the conductive layer 20b, which is the upper electrode of the capacitor C, is connected to the second external connection terminal P2 via the second internal electrode 70b only. Thus, the conductor path connecting the upper electrode of the capacitor C to the second external connection terminal P2 is short; accordingly, the parasitic inductance of this conductor path is small. As the inductance of the conductor path L2 in the equivalent circuit shown in FIG. 4 becomes smaller, the effect of letting noise generated in the semiconductor chip 110 escape to the ground electrode, i.e., the effect of suppressing leakage of noise generated in the semiconductor chip 110 to the power supply VDD, increases. The capacitor C with the above-described configuration also has a small parasitic inductance (or equivalent series inductance). Thus, the semiconductor device 1 exhibits excellent performance as an LC filter.

In addition, in the semiconductor package 100, the semiconductor device 1 is bonded to the semiconductor chip 110 by flip-chip bonding. This is why the conductor path L2 in the equivalent circuit shown in FIG. 4 is shorter than in the case where the semiconductor device 1 is bonded to the semiconductor chip 110 by wire bonding. This means that the inductance of the conductor path L2 is smaller. Accordingly, when the above-described configuration is adopted for the semiconductor package 100, the noise blocking effect is higher than in the case where the semiconductor device 1 is bonded to the semiconductor chip 110 by wire bonding.

Furthermore, in the semiconductor device 1, the inductor L1 is adjacent to the capacitor C with the insulating layer 60a and the second internal electrode 70b interposed therebetween. Thus, heat generated in the inductor L1 is quickly transferred to the capacitor C. The heat transferred from the inductor L1 to the capacitor C is then quickly transferred in the depth direction of the recesses TR. This makes the semiconductor device 1 excellent in radiation performance, and thus have a large allowable current.

In the semiconductor package 100, the inductor L1 is interposed between the semiconductor chip 110 and the capacitor C. Thus, the heat transferred to the capacitor C may be quickly transferred to the outside of the semiconductor package 100.

The semiconductor device 1 is also excellent in heat resistance. Moreover, the semiconductor device 1 may have almost the same coefficient of thermal expansion as the semiconductor chip 110. Thus, the semiconductor package 100 may achieve excellent heat resistance.

<Modifications>

Various modifications can be made to the semiconductor device 1 and the semiconductor package 100.

For example, in the configuration described with reference to FIGS. 1 and 2, the conductive layer 20a, which is the lower electrode of the capacitor C, is connected to one end of the inductor L1, and the conductive layer 20b, which is the upper electrode of the capacitor C, is connected to the second external connection terminal P2. Instead, it is possible to connect the conductive layer 20b, which is the upper electrode of the capacitor C, to one end of the inductor L1 and connect the conductive layer 20a, which is the lower electrode of the capacitor C, to the second external connection terminal P2. When this configuration is employed, the parasitic capacitance that occurs between the capacitor C and the inductor L1 can be decreased.

In the configuration described with reference to FIGS. 1 and 2, the insulating layer 60a and inductor L1 are formed on the first main surface S1. It is possible to form the insulating layer 60a and the inductor L1 on the second main surface S2, form through-holes in the substrate 10 and the like, and connect the inductor L1 to the first external connection terminal P1 and the third external connection terminal P3 via the through-holes.

The semiconductor device 1 may be bonded to the semiconductor chip 110 by wire bonding, instead of flip-chip boding.

The semiconductor chip 110 may be bonded to the wiring board 140 by flip-chip bonding, instead of wire bonding.

The semiconductor package 100 may be a package other than the BGA, such as a quad flat package (QFP). In this case, the semiconductor package 100 can include a lead frame, instead of the wiring board 140.

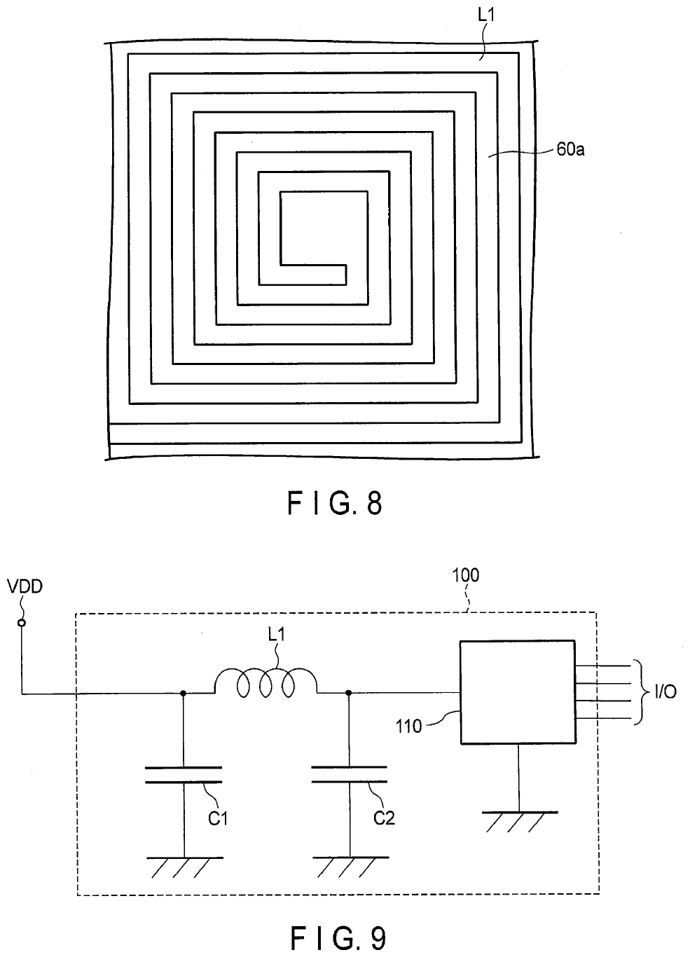

The inductor L1 may be an inductor other than the meander inductor. For example, the inductor L1 may be a spiral inductor shown in FIG. 8.

The LC filter constituted by the semiconductor device 1 is not limited to the L-type filter shown in FIG. 4. For example, the semiconductor device 1 may constitute a Π-type filter shown in FIG. 9. In this case, the semiconductor device 1 includes two capacitors C1 and C2, which are similar to the capacitor C, instead of one capacitor C.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a layer stack including
a conductive substrate containing semiconductor material and including a first main surface provided with one or more recesses and a second main surface opposite to the first main surface,
a conductive layer covering at least part of the first main surface and side walls and bottom surfaces of the one or more recesses, and
a dielectric layer interposed between the conductive substrate and the conductive layer, the conductive layer and a portion of the conductive substrate adjacent to the dielectric layer being an upper electrode and a lower electrode of a capacitor, respectively;
an insulating layer provided on the capacitor or on the second main surface; and
an inductor provided on the insulating layer at a position of the capacitor.

2. The semiconductor device according to claim 1, wherein the first main surface is provided with a plurality of recesses as the one or more recesses, or provided with the one or more recesses in such a manner that a plurality of pillar-like projections are provided.

3. The semiconductor device according to claim 1, wherein the first main surface is provided with a plurality of trenches arranged in a width direction as the one or more recesses.

4. The semiconductor device according to claim 1, wherein the inductor is a meander inductor or a spiral inductor.

5. The semiconductor device according to claim 1, wherein the insulating layer is provided on the capacitor, and the inductor faces the capacitor with the insulating layer interposed therebetween.

6. The semiconductor device according to claim 1, wherein one of the upper electrode and the lower electrode is connected to one end of the inductor.

7. The semiconductor device according to claim 1, further comprising:
a first external connection terminal connected to one end of the inductor and one of the upper electrode and the lower electrode;
a second external connection terminal connected to another one of the upper electrode and the lower electrode; and
a third external connection terminal connected to another end of the inductor.

8. The semiconductor device according to claim 7, wherein the first external connection terminal, the second external connection terminal, and the third external connection terminal are arranged to face the first main surface.

9. The semiconductor device according to claim 7, further comprising bonding conductors provided on the first external connection terminal, the second external connection terminal, and the third external connection terminal.

10. A semiconductor package comprising:
a semiconductor chip including an integrated circuit; and
the semiconductor device according to claim 7, the first external connection terminal being connected to the integrated circuit.

11. The semiconductor package according to claim 10, wherein the semiconductor device is bonded to the semiconductor chip by flip-chip bonding.

12. The semiconductor package according to claim 10, further comprising a wiring board on which the semiconductor chip is mounted.
